(19) United States
(12) Patent Application Publication
(10) Pub. No.: US 2003/0135994 A1
(43) Pub. Date: Jul. 24, 2003

(54) Printed circuit board and manufacturing method therefor

(75) Inventors: Takashi Shutou, Nagano (JP); Yasuhito Takahashi, Nagano (JP); Kenji Iida, Nagano (JP); Kenji Takano, Nakano (JP); Yukio Miyazaki, Nagano (JP)

Correspondence Address: STAAS & HALSEY LLP, 700 11TH STREET, NW, SUITE 500, WASHINGTON, DC, 20001, US

(73) Assignee: Fujitsu Limited, Kawasaki (JP)

(21) Appl. No.: 10/342,298

(22) Filed: Jan. 15, 2003

(30) Foreign Application Priority Data
Jan. 18, 2002 (JP) 2002-009747

(51) Int. Cl. H05K 3/36; H05K 3/30

(52) U.S. Cl. 29/830; 29/832; 29/846; 174/255; 174/266; 174/259

(57) ABSTRACT

The present invention relates to a method for manufacturing a printed circuit board, and the method comprises forming penetrating holes in predetermined positions of an insulating substrate, then forming resist films having a predetermined pattern on the front and the rear surfaces of the insulating substrate; plating the insulating substrate provided with the resist films so as to form conductive plating patterns on the front and the rear surfaces of the insulating substrate and conductive paths on the inside surfaces of the penetrating holes, the conductive plating patterns being connected to each other via the conductive paths; and subsequently removing the resist films.

### BACKGROUND OF THE INVENTION

1. Field of the Invention

The present invention relates to methods for manufacturing printed circuit boards used as a core material for forming a multilayer printed circuit board.

2. Description of the Related Art

FIG. 3 is a cross-sectional view of a multilayer printed circuit board having a conventional interstitial via hole structure. Reference mark 30 indicates the multilayer printed circuit board, reference mark 31 indicates a double-sided printed circuit board, reference marks 31A and 31B each indicate a conductive circuit, reference mark 31C indicates a through hole, reference mark 31D indicates a hole-filling resin, reference mark 31E indicates a insulating substrate, reference mark 32 indicates a single-sided printed circuit board, reference mark 32A indicates an insulating substrate, reference mark 33 indicates a field via hole, and reference mark 32B indicates a conductive circuit.

On each of the two surfaces of the double-sided printed circuit board 31 used as a core material, at least one single-sided printed circuit board 32 is provided with at least one prepreg 35 provided therebetween. In each of these single-sided printed circuit boards 32, the conductive field via hole 33 penetrating the insulating substrate 32A is formed. These via holes electrically connect the conductive circuits 32B of the single-sided printed circuit boards 32 to the conductive circuits 31A and 31B of the double-sided printed circuit board 31. As shown in this figure, when a plurality of the single-sided printed circuit boards 32 is laminated to each other on each side of the double-sided printed circuit board 31, the field via hole 33 of the single-sided printed circuit board located at the outer side is electrically connected to the conductive circuit 32 of the adjoining single-sided printed circuit board 32 located at the inner side.

In addition, in the double-sided printed circuit board 31, in order to connect the conductive circuits 31A and 31B to each other, which are provided on the two surfaces, the through hole 31C is formed. This through hole 31C is formed by steps of forming a hole in an insulating substrate 31E forming the double-sided printed circuit board 31, sequentially performing chemical plating and electroplating on the inside surface of the hole mentioned above to form a hollow cylindrical conductive path, filling the through hole thus formed with the hole-filling resin 31D, and polishing the two surfaces of the double-sided printed circuit board 31.

As described above, in the method for manufacturing the double-sided printed circuit board 31 used as a core material, the insulating substrate 31E is irradiated with a laser to form the hole therein, and the conductive path is then formed by a through hole plating method. Next, conductive patterns are formed on the surfaces of the insulating substrate, thereby forming the double-sided printed circuit board 31. However, since the conductive path and the conductive patterns are formed in separate steps, the number of steps is increased. In addition, when a subtractive process is used for forming patterns, there has been a serious problem in that a pattern having fine pitches cannot be obtained.

### SUMMARY OF THE INVENTION

Accordingly, an object of the present invention is to provide a printed circuit board on which high-density mounting can be realized and a manufacturing method therefor in which the number of manufacturing steps is decreased since conductive plating patterns and conductive paths are formed in the same step, and patterns having fine pitches are formed.

To these ends, according to one aspect of the present invention, a method for manufacturing a printed circuit board, comprises a step of forming penetrating holes in predetermined positions of an insulating substrate; a step of forming resist films each having a predetermined pattern on the front and the rear surfaces of the insulating substrate provided with the penetrating holes; a plating step of plating the insulating substrate provided with the resist films so as to form conductive plating patterns on the front and the rear surfaces of the insulating substrate and conductive paths on the inside surfaces of the penetrating holes, the conductive plating patterns being connected to each other via the conductive paths; and a subsequent removing step of removing the resist films. Accordingly, the number of manufacturing steps can be decreased since the conductive paths and the conductive plating patterns can be formed in the same step, and the patterns having fine pitches can be formed, whereby a printed circuit board on which high-density mounting is realized and a manufacturing method therefor can be provided.

According to the method described above, the plating step is preferably performed by electroless copper plating. As a result, the number of steps is decreased since the conductive paths and the conductive plating patterns are formed in the same step, and the patterns having fine pitches can be formed, whereby a printed circuit board on which high-density mounting is realized and a manufacturing method therefor can-be provided.

According to the method described above, after the conductive paths are formed on the inside surfaces of the penetrating holes, it is preferable that the plating step be continuously performed until the entire surface of the insulating substrate, including the positions at which the penetrating holes are formed, is approximately planarized. As a result, the number of steps is decreased since the conductive paths and the conductive plating patterns are formed in the same step, and the patterns having fine pitches can be formed, whereby a printed circuit board on which high-density mounting is realized and a manufacturing method therefor can be provided.

The method described above may further comprise a step of etching the surfaces of the conductive plating patterns provided on the front and the rear surfaces of the insulating substrate before the removing step is performed. As a result, the irregularities of the surfaces of the conductive plating patterns can be decreased, and in addition, the thicknesses thereof can be adjusted.

In the method described above, the plating step is preferably continued until the thickness of the conductive plating pattern on the front surface of the insulating substrate becomes larger than the radius of each penetrating hole. As a result, the number of steps is decreased since the conductive paths and the conductive plating patterns are formed in the same step, and the patterns having fine pitches can be formed, whereby a printed circuit board on which high-density mounting is realized and a manufacturing method therefor can be provided.

The method described above may further comprise a step of forming insulating layers on the conductive plating patters connected to each other, and a step of forming circuit patterns on the insulating layers so as to form a build-up substrate. As a result, the number of steps is decreased since the conductive paths and the conductive plating patterns are formed in the same step, and the patterns having fine pitches can be formed, whereby a printed circuit board on which high-density mounting is realized and a manufacturing method therefor can be provided.

In accordance with another aspect of the present invention, a method for manufacturing a printed circuit board, comprises a step of preparing a substrate formed of two resin layers with an intermediate resin layer which is provided therebetween and which has a predetermined decomposition temperature higher than that of each of the two resin layers; an irradiating step of irradiating predetermined positions of the substrate with a laser for forming penetrating holes so that the diameter of each hole formed in each of the two resin layers is larger than that formed in the intermediate resin layer; a step of forming resist films each having a predetermined pattern on the front and the rear surfaces of the substrate provided with the penetrating holes; a plating step of plating the substrate provided with the resist films so as to form conductive plating patterns on the front and the rear surfaces of the insulating substrate and conductive paths on the inside surfaces of the penetrating holes, the conductive plating patterns being connected to each other via the conductive paths; and a subsequent removing step of removing the resist films. Accordingly, since the substrate formed of the materials having different decomposition temperatures from each other is used, when hole formation and etching are performed for the substrate, the diameter of each hole formed in the material having a high decomposition temperature is smaller than that formed in the material having a low decomposition temperature. When plating is performed for the substrate, this smaller hole is closed, and the conductive path formed by plating grows simultaneously toward the upper side and the lower side of the position at which this smaller hole is formed. Accordingly, compared to the case in which the conductive path grows in one direction in the hole, the plating step described above can be performed in a short period of time.

The method according to said another aspect may further comprise a step of etching the substrate using permanganic acid, the substrate being provided with the penetrating holes formed in the irradiating step. As a result, a resin remaining in the penetrating holes can be easily removed.

In accordance with still another aspect of the present invention, a printed circuit board comprises an insulating resin substrate provided with penetrating holes; conductive plating patterns provided on the front and the rear surfaces of the insulating resin substrate; and conductive paths provided on the inside surfaces of the penetrating holes and connecting the conductive plating patterns to each other; wherein the conductive plating patterns and the conductive paths are simultaneously formed by copper plating. Accordingly, a sufficient plating amount can be filled into each of the penetrating holes, and in addition, conductive plating patterns having a desired thickness can be simultaneously obtained.

The printed circuit board of the present invention described above may further comprise insulating layers provided on the front and the rear surfaces of the printed circuit board; and circuit patterns provided on the respective insulating layers so as to have a build-up structure. As a result, the number of steps is decreased since the conductive paths and the conductive plating patterns are formed in the same step, and the patterns having fine pitches can be formed, whereby a printed circuit board on which high-density mounting is realized and a manufacturing method therefor can be provided.

### BRIEF DESCRIPTION OF THE DRAWINGS

FIGS. 1A to 1G are schematic views for illustrating steps for manufacturing a printed circuit board according to a first embodiment of the present invention;

FIGS. 2A to 2G are schematic views for illustrating steps for manufacturing a printed circuit board according to a second embodiment of the present invention; and

FIG. 3 is a cross-sectional view showing a multilayer printed circuit board having a conventional interstitial via hole structure.

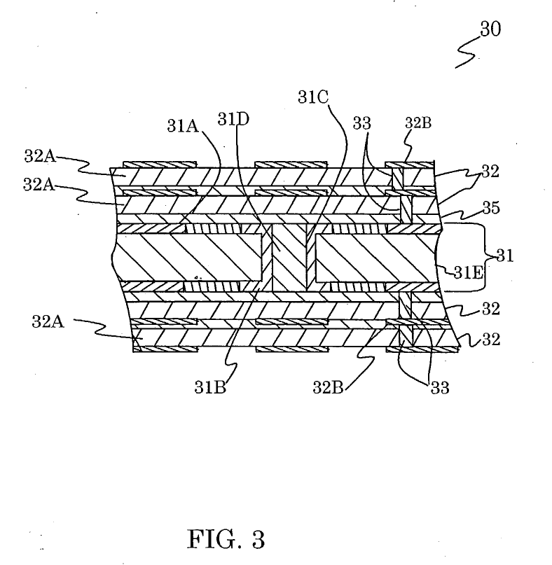

### DESCRIPTION OF THE PREFERRED EMBODIMENTS

### First Embodiment

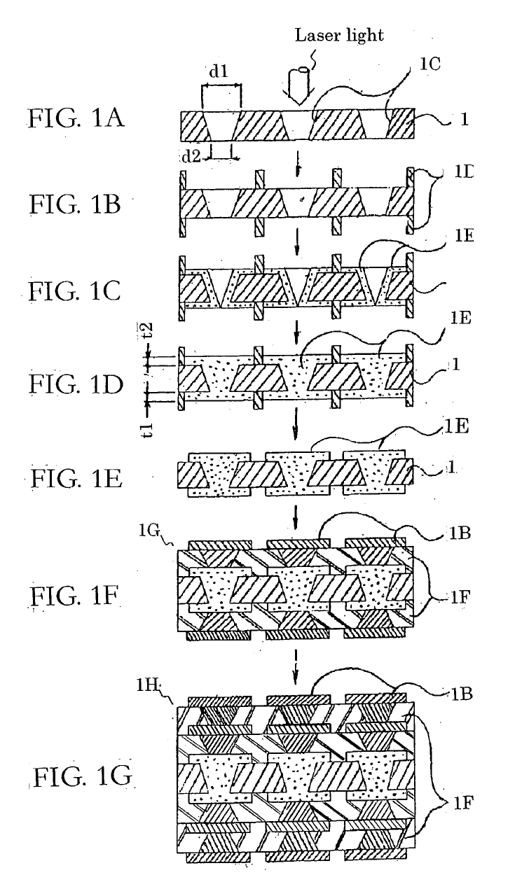

FIGS. 1A to 1G are views for illustrating steps for manufacturing a printed circuit board according to a first embodiment of the present invention.

Reference mark 1 indicates an insulating substrate, reference mark 1B indicates a conductive circuit, reference mark 1C indicates a penetrating hole (thorough hole), reference mark 1D indicates a dry film resist, reference mark 1E indicates a plating layer, and reference mark 1F indicates an insulating material.

As shown in FIG. 1A, the insulating substrate 1 is first prepared. The insulating substrate 1 may be formed of, for example, a glass cloth epoxy resin, a glass cloth bismaleimide triazine resin, a glass cloth poly(phenylene ether) resin, or a polyimide-aramid liquid crystal polymer. The insulating substrate 1 which is prepared is formed of, for example, a thermosetting epoxy resin, and the thickness thereof is approximately 50 μm. In this insulating substrate 1, the penetrating holes 1C are provided by laser machining. The laser machining is performed by a pulse generation type CO₂ gas laser beam machine. The machining is performed under the conditions in which the pulse energy is in the range of 0.1 to 1.0 mJ, the pulse width is in the range of 1 to 100 μs, and the number of shots is in the range of 2 to 50. The penetrating hole 1C formed by this laser machining has a diameter d1 of approximately 60 μm and a diameter d2 of approximately 40 μm. Subsequently, in order to remove a resin remaining in the penetrating holes 1C, a desmear process is performed by oxygen plasma discharge, corona discharge, treatment using potassium permanganate, or the like. In addition, on the inside surfaces of the penetrating holes 1C and the entire front and rear side surfaces of the insulating substrate 1, electroless plating is performed. The layer formed by this electroless plating has a thickness of approximately 4,500 Å.

Next, the dry film resist are provided on the front and the rear surfaces of the insulating substrate 1. In particular, this dry film resist is an alkaline development type and has photosensitivity. The thickness of this dry film resist is approximately 40 μm. Subsequently, exposure and development of the dry film resists are performed, thereby forming resist films 1D each having a desired pattern are formed as shown in FIG. 1B.

Next, FIG. 1C is a view showing a state in which plating treatment is being performed. The plating treatment is performed by a DC electroplating method using the layer formed by the electroless plating in the step shown in FIG. 1A as an electrode. In addition, a material forming this plating layer 1E may be copper, tin, silver, solder, an alloy of copper and tin, an alloy of copper and silver, or the like, and any type of metal which can be used for plating may be used. The insulating substrate 1 provided with the dry film resists 1D, which is obtained in the step shown in FIG. 1B, is immersed in a plating bath. Accordingly, the plating layer 1E grows simultaneously on the inside surfaces of the penetrating holes 1C and on the front and the rear surfaces of the insulating substrate 1, so that the thickness of the plating layer 1E is increased. While the plating is being performed, the plating layer 1E grows on the inside surfaces, each having a cross-section inclined from the bottom surface portion to the top surface portion, of the penetrating holes 1C, and consequently, the bottom portion of each of the penetrating holes 1C is closed by the plating layer 1E.

In addition, as shown in FIG. 1D, the plating is continuously performed for the insulating substrate 1 in the state shown in FIG. 1C so that thickness t1 of the plating layer 1E formed on the front and the rear surfaces of the insulating substrate 1 is increased to approximately 60 μm. Accordingly, the front and the rear surfaces of the insulating substrate 1, including the positions in which the penetrating holes are formed, are approximately planarized. Subsequently, in order to decrease irregularities of the plating layer 1E formed on each of the front and the rear surfaces of the insulating substrate 1 and to adjust the thickness thereof, etching is performed. An etching solution for this etching contains copper chloride.

By using a semi-additive method, the number of steps is decreased since the conductive paths and the conductive plating patterns are formed in the same step, and in addition, and the patterns having fine pitches can be formed, whereby a printed circuit board on which high-density mounting can be achieved and a manufacturing method therefor can be obtained.

Next, as shown in FIG. 1E, the dry film resists 1D provided on the front and the rear surfaces of the insulating substrate 1 are removed. A removing method therefor is performed by using a remover. The remover used in this embodiment, for example, is an alkaline-based remover. Accordingly, after the dry film resists 1D are removed, the electroless plating layer formed in the step shown in FIG. 1A is partially exposed as shown in FIG. 1E. Subsequently, the electroless plating layer 1E is etched. The etching solution used in this embodiment, for example, is a mixture of hydrogen peroxide and sulfuric acid.

Next, as shown in FIG. 1F, after layers of the insulating material 1F are formed on the fron and the rear surfaces of the insulating substrate 1 and the electrodeless plating layer 1E, circuit patterns are further formed on the layers of the insulating material 1F, thereby forming a build-up substrate. As a method for applying the insulating materials 1F, spin coating, curtain coating, spray coating, or vacuum lamination pressing may be mentioned by way of example. The insulating material used in this embodiment, for example, is a thermosetting epoxy resin. The thickness of the layer made of the insulating material 1F thus applied is in the range of approximately 30 to 50 μm. In addition, on the layers of the insulating material 1F provided on both surfaces of the insulating substrate 1, the circuit patterns mentioned above are formed, thereby forming a multilayer structure. After a conductive material is provided on each layer of the insulating material 1F, the pattern formation mentioned above is primarily performed by applying a resist material on the conductive material, performing exposure and development of the resist material, and then etching the conductive material. In particular, a four-layered printed circuit board 1G is formed.

Furthermore, as shown in FIG. 1G, on the topmost and the bottommost surfaces of the four-layered printed circuit board 1G thus formed, other circuit patterns are formed, thereby forming a build-up substrate. In particular, a six-layered printed circuit 1H board is obtained.

### Second Embodiment

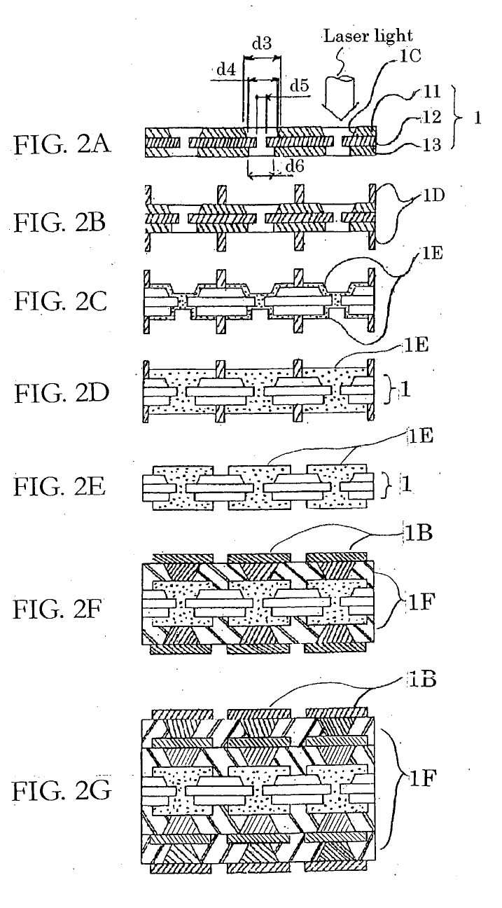

FIGS. 2A to 2G are views for illustrating steps for manufacturing a printed circuit board according to a second embodiment of the present invention. Steps shown in FIGS. 2A, 2B, 2C, 2D, 2E, 2F, and 2G of the second embodiment correspond to the steps shown in FIGS. 1A, 1B, 1C, 1D, 1E, 1F, and 1G of the first embodiment, respectively. Hereinafter, points of the second embodiment different from the first embodiment will be mainly described.

An insulating substrate 1 shown in FIG. 2A is first prepared. This insulating substrate 1 has a three-layered structure in which a second insulating substrate 12 is provided on the front surface of a first insulating substrate 11, and a third insulating substrate 13 is provided on the rear surface thereof. The first insulating substrate 11, the second insulating substrate 12, and the third insulating substrate 13 are formed of materials selected from those mentioned in the first embodiment. In particular, the first insulating substrate 11 is formed of an aramid or epoxy-based resin. This first insulating substrate 11 has a thickness of approximately 25 μm and a thermal decomposition temperature of approximately 500° C. In addition, the second and the third insulating substrates 12 and 13 provided, respectively, on the front and the rear surfaces of the first insulating substrate 11 are formed of the same material. In particular, the second and the third insulating substrates 12 and 13 are formed of a thermosetting epoxy resin. These second and the third insulating substrates 12 and 13 each have a thickness of approximately 12.5 μm and a thermal decomposition temperature of approximately 300° C. The penetrating holes 1C are formed in this insulating substrate 1 by laser machining. The laser machining is performed as in the first embodiment. However, since the decomposition temperature of the first insulating substrate 11 is different from that of each of the second and the third insulating substrates 12 and 13, the hole diameter of the first insulating substrate 11 is different from that of each of the second and the third insulating substrates 12 and 13. The hole formed in the second insulating substrate 12 having a low decomposition temperature has a diameter larger than that of the first insulating substrate 11 having a high decomposition temperature. In more detail, the hole formed in the second insulating substrate 12 has a tapered cross-sectional shape. In order to increase the difference between the hole diameter of the second insulating substrate 12 and that of the first insulating substrate 11, the insulating substrate 11 having the penetrating holes 1C is subsequently etched. The etching solution used for this etching contains permanganic acid. The second and the third insulating substrates 12 and 13 formed of a thermosetting epoxy resin are easily etched compared to the first insulating substrate 11 formed of an aramid or epoxy-based resin. As a result, diameter d3 of the hole at the top surface of the second insulating substrate 12 and diameter d4 at the bottom surface thereof thus formed are approximately 50 and 40 μm, respectively. Diameter d5 of the hole formed in the first insulating substrate 11 is approximately 30 μm, and diameter d6 of the hole formed in the third insulating substrate 13 is approximately 40 μm. These three holes form the penetrating hole 1C. Electroless plating is performed over the entire inside surface of the penetrating holes 1C and the entire front and rear surfaces of the insulating substrate 1. This thickness of a layer formed by electroless plating is approximately 4,500 Å.

Next, as shown in FIG. 2B, in a manner equivalent to that in the first embodiment, dry film resists 1D are provided on the front and the rear surfaces of the insulating substrate 1.

Next, FIG. 2C is a view showing a state in which plating is being performed. As in the first embodiment, the insulating substrate 1 provided with the dry film resists 1D formed in the step shown in FIG. 2B is immersed in a plating bath. Accordingly, the plating layer 1E simultaneously grows over the entire inside surfaces of the penetrating holes 1C and the entire front and rear surfaces of the insulating substrate 1, so that the thickness of the plating layer 1E is increased. While the plating is being performed, the holes formed in the first insulating substrate 11 are first filled with the growing plating layer 1E, so that the holes described above are closed thereby. Since the plating layer 1E grows simultaneously toward the upper side and the lower side of the position at which the hole is formed in the first insulating substrate 11, the plating time can be shortened compared to the case in which the plating layer grows in one direction in the hole as in the first embodiment.

Subsequent steps shown in FIGS. 2D to 2G are performed in that order in a manner equivalent to that in the first embodiment.

In this embodiment, as described above, the plating layer is obtained by electroless plating in the step shown in FIG. 2A, and electroplating is then performed in the step shown in FIG. 2C on the electroless plating layer mentioned above, thereby forming the plating layer having a desired thickness. However, the plating layer having a desired thickness may be formed only by electroless plating performed in the step shown in FIG. 2A.

As has thus been described with reference to the first and the second embodiments, when the method of the present invention for manufacturing a printed circuit board is used, the number of steps can be decreased since the conductive paths and the conductive plating patterns can be formed in the same step, and the patterns having fine pitches can be formed, whereby a printed circuit board on which high-density mounting can be realized and a manufacturing method therefor can be obtained.

What is claimed is:

1. A method for manufacturing a printed circuit board, comprising:
a step of forming penetrating holes in predetermined positions of an insulating substrate;
a step of forming resist films each having a predetermined pattern on the front and the rear surfaces of the insulating substrate provided with the penetrating holes;
a plating step of plating the insulating substrate provided with the resist films so as to form conductive plating patterns on the front and the rear surfaces of the insulating substrate and conductive paths on the inside surfaces of the penetrating holes, the conductive plating patterns being connected to each other via the conductive paths; and
a subsequent removing step of removing the resist films.

2. A method for manufacturing a printed circuit board, according to claim 1, wherein the plating step is performed by electroless copper plating.

3. A method for manufacturing a printed circuit board, according to claim 1 or 2, wherein, after the conductive paths are formed on the inside surfaces of the penetrating holes, the plating step is continuously performed until the entire surface of the insulating substrate, including the positions at which the penetrating holes are formed, is approximately planarized.

4. A method for manufacturing a printed circuit board, according to claim 1, further comprising a step of etching the surfaces of the conductive plating patterns provided on the front and the rear surfaces of the insulating substrate before the subsequent removing step is performed.

5. A method for manufacturing a printed circuit board, according to claim 1 or 2, wherein the plating step is continuously performed until the thickness of the conductive plating pattern on the front surface of the insulating substrate becomes larger than the radius of each of the penetrating holes.

6. A method for manufacturing a printed circuit board, according to one of claims 1, 2, and 4, further comprising a step of forming insulating layers on the conductive plating patters connected to each other, and a step of forming circuit patterns on the insulating layers so as to form a build-up substrate.

7. A method for manufacturing a printed circuit board, according to claim 3, further comprising a step of forming insulating layers on the conductive plating patters connected to each other, and a step of forming circuit patterns on the insulating layers so as to form a build-up substrate.

8. A method for manufacturing a printed circuit board, according to claim 5, further comprising a step of forming insulating layers on the conductive plating patters connected to each other, and a step of forming circuit patterns on the insulating layers so as to form a build-up substrate.

9. A method for manufacturing a printed circuit board, comprising:
a step of preparing a substrate formed of two resin layers with an intermediate resin layer which is provided therebetween and which has a predetermined decomposition temperature higher than that of each of the two resin layers;
an irradiating step of irradiating predetermined positions of the substrate with a laser for forming penetrating holes so that the diameter of each hole formed in each of the two resin layers is larger than that formed in the intermediate resin layer;
a step of forming resist films each having a predetermined pattern on the front and the rear surfaces of the substrate provided with the penetrating holes;
a plating step of plating the substrate provided with the resist films so as to simultaneously form conductive plating patterns on the front and the rear surfaces of the insulating substrate and conductive paths on the inside surfaces of the penetrating holes, the conductive plating patterns being connected to each other via the conductive paths; and
a subsequent removing step of removing the resist films.

10. A method for manufacturing a printed circuit board, according to claim 9, further comprising a step of etching the substrate using permanganic acid, the substrate being provided with the penetrating holes formed in the irradiating step.

11. A printed circuit board comprising:
an insulating resin substrate provided with penetrating holes;
conductive plating patterns provided on the front and the rear surfaces of the insulating resin substrate; and
conductive paths which are provided on the inside surfaces of the penetrating holes;
wherein the conductive plating patterns and the conductive paths are simultaneously formed by copper plating.

12. A printed circuit board according to claim 11, further comprising:
insulating layers provided on the front and the rear surfaces of the printed circuit board; and circuit patterns provided on the insulating layers so as to have a build-up structure.

13. A method for manufacturing a printed circuit board, comprising:
a step of forming penetrating holes in predetermined positions of an insulating substrate;
a step of forming resist films each having a predetermined pattern on the front and the rear surfaces of the insulating substrate;
a step of plating the insulating substrate so as to form conductive plating patterns on the front and the rear surfaces of the insulating substrate and conductive paths on the inside surfaces of the penetrating holes, the conductive plating patterns being connected to each other via the conductive paths; and
a step of removing the resist films.

14. A method for manufacturing a printed circuit board, comprising:
a step of preparing a substrate formed of two resin layers with an intermediate resin layer which is provided therebetween and which has a predetermined decomposition temperature higher than that of each of the two resin layers;
an irradiating step of irradiating predetermined positions of the substrate with a laser for forming penetrating holes so that the diameter of each hole formed in each of the two resin layers is larger than that formed in the intermediate resin layer;
a step of forming resist films each having a predetermined pattern on the front and the rear surfaces of the substrate;
a step of plating the substrate so as to simultaneously form conductive plating patterns on the front and the rear surfaces of the insulating substrate and conductive paths on the inside surfaces of the penetrating holes, the conductive plating patterns being connected to each other via the conductive paths; and
a removing step of removing the resist films.
